(19) United States
(12) Patent Application Publication
(10) Pub. No.: US 2015/0359110 A1
(43) Pub. Date: Dec. 10, 2015

(54) INNER LAYER DEPTH DETECTION DURING CONTROLLED-DEPTH DRILLING USING CONTINUITY TEST COUPON

(71) Applicant: Keysight Technologies, Inc., Minneapolis, MN (US)

(72) Inventor: Brian S. Wright, Santa Rosa, CA (US)

(21) Appl. No.: 14/298,002

(22) Filed: Jun. 6, 2014

(51) Int. Cl. H05K 3/46; H05K 3/00

(52) U.S. Cl. CPC H05K 3/4685; H05K 3/0047; H05K 2203/163

(57) ABSTRACT

A method of detecting depth of a buried target disposed over an intermediate layer within a multi-layer substrate includes forming a test coupon on the intermediate layer during manufacture of the multi-layer substrate, the test coupon including a trace with probe sites at opposite ends; drilling a hole through the trace of the test coupon within the multi-layer substrate; monitoring electrical continuity of the test coupon during the drilling; and determining a depth of the buried target responsive to the monitoring. A hole may then be drilled based on the determined depth.

### BACKGROUND

Vias are conventionally used to electrically connect an inner layer (such as a copper layer) of a single or multiple lamination printed circuit board (PCB) to an external layer of the PCB. Vias are formed by drilling a hole into the PCB, and then plating the drilled hole to connect multiple PCB layers together. A blind via in particular connects only one external layer of the PCB to one or more inner layers of the PCB, without connecting the top external layer of the PCB to the bottom external layer of the PCB. That is, the blind via is produced by drilling techniques that do not drill entirely through the PCB from the top external layer to the bottom external layer. However, there currently is no way to precisely connect a mechanically-drilled blind via to the inner layers of a PCB.

For example, when drilled mechanically, a blind via will typically extend past a buried target layer due to drill overshoot, creating a long stub extending below the buried target layer. The stub is a plated feature. An electrical signal externally applied to the blind via from an external layer of the PCB will typically be conducted beyond the buried target layer along the stub, and may reflect off the bottom of the blind via (the stub) back to the buried, target layer, degrading the quality of the signal provided to the buried, target layer. Signal quality degradation correlates directly with increase in stub length. Also, the higher the signal frequency, the more sensitive the signal is to stub induced degradation.

There is therefore a need to provide a way to precisely measure and control the depth of a mechanically-drilled hole with respect to a buried target layer.

### SUMMARY

In a representative embodiment, a method of detecting depth of a buried target disposed over an intermediate layer within a multi-layer substrate includes forming a test coupon over the intermediate layer during manufacture of the multi-layer substrate, the test coupon comprising a trace with probe sites at opposite ends; drilling a hole through the trace of the test coupon within the multi-layer substrate; monitoring electrical continuity of the test coupon during said drilling; and determining a depth of the buried target responsive to said monitoring.

In another representative embodiment, a method of connecting a via to a buried target disposed over an intermediate layer within a multi-layer substrate includes forming a test coupon over the intermediate layer during manufacture of the multi-layer substrate; the test coupon comprising a trace having probe sites at opposite ends; drilling a first hole through the trace of the test coupon within the multi-layer substrate; monitoring electrical continuity of the test coupon during said drilling of the first hole; determining a depth of the buried target responsive to said monitoring; drilling a second hole to the buried target within the multi-layer substrate, the second hole having a depth selected responsive to the determined depth; and plating the second hole to form a via connected to the buried target.

In a still further representative embodiment, a method of connecting a via to a buried target disposed over a first intermediate layer within a multi-layer substrate, the multi-layer substrate having opposite first and second surfaces, the method includes forming a test coupon over a second intermediate layer below the first intermediate layer during manufacture of the multi-layer substrate, the test coupon comprising a trace with probe sites at opposite ends; drilling a first hole from the second surface through the trace of the test coupon within the multi-layer substrate; monitoring electrical continuity of the test coupon during said drilling of the first hole; determining a depth of the second intermediate layer from the second surface responsive to said monitoring; drilling a second hole entirely through the multi-layer substrate and the buried target; plating the second hole to form a via connected to the buried target; and drilling a third hole from the second surface toward the buried target, wherein the third hole has a depth from the second surface selected responsive to the determined depth and has a diameter greater than a diameter of the second hole, and wherein the second and third holes are aligned with each other.

### BRIEF DESCRIPTION OF THE DRAWINGS

The illustrative embodiments are best understood from the following detailed description when read with the accompanying drawing figures. Wherever applicable and practical, like reference numerals refer to like elements.

FIG. 1 is a block diagram illustrating a drilling system, according to a representative embodiment.

FIG. 2 is a plan view illustrating a multi-layer substrate including a test coupon and a main circuit area, according to a representative embodiment.

FIG. 3 is a cross-sectional view of a multi-layer substrate including a test coupon and a buried target, illustrative of a method of forming a blind via according to a representative embodiment.

FIG. 4 is a cross-sectional view of a multi-layer substrate including first and second test coupons and a buried target, illustrative of a method of forming a blind via, according to a representative embodiment.

FIG. 5 is a cross-sectional view of a multi-layer substrate including a test coupon and a buried target, illustrative of a method of forming a through via according to a representative embodiment.

FIG. 6 is a plan view illustrating a test coupon with a corresponding drill hole at a first location, according to a representative embodiment.

FIG. 7 is a plan view illustrating a test coupon with a corresponding drill hole at a second location, according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it should be understood that the drawings and the various elements depicted therein are not drawn to scale. Further, relative terms, such as “above,” “below,” “top,” “bottom,” “upper,” “lower,” “left,” “right,” “vertical” and “horizontal,” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be “below” that element. Likewise, if the device were rotated 90 degrees with respect to the view in the drawings, an element described as “vertical.” for example, would now be “horizontal.”

Generally, it should also be understood that as used in the specification and appended claims, the terms “a”, “an” and “the” include both singular and plural referents, unless the context clearly dictates otherwise. Thus, for example, “a device” includes one device and plural devices.

As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As a farther example, “substantially removed” means that one skilled in the art would consider the removal to be acceptable.

As used in the specification and the appended claims and in addition to its ordinary meaning, the term “approximately” means to within an acceptable limit or amount to one having ordinary skill in the art. For example, “approximately the same” means that one of ordinary skill in the art would consider the items being compared to be the same.

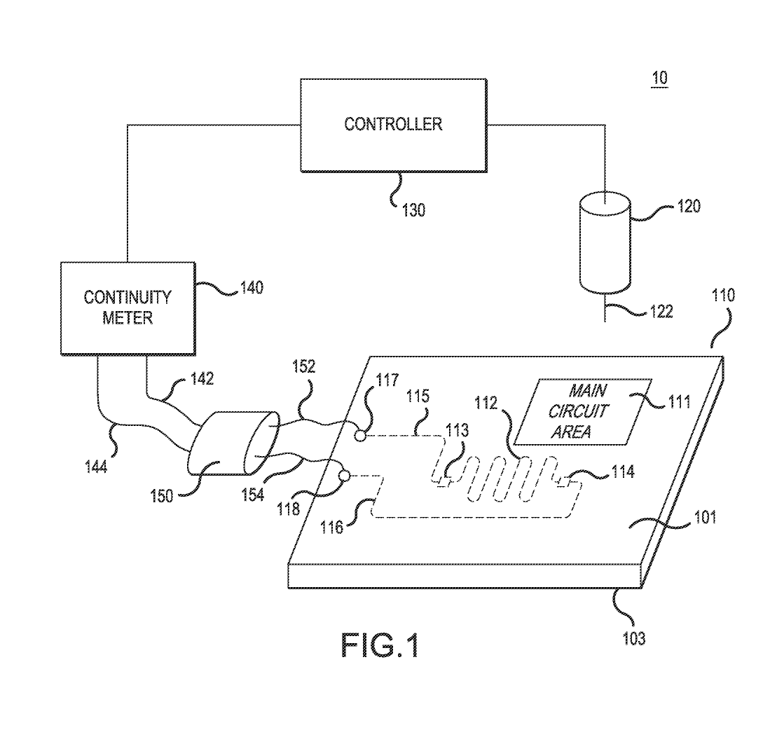

FIG. 1 is a block diagram illustrating a drilling system 10, according to a representative embodiment.

Referring to FIG. 1, in a representative embodiment, drilling system 10 includes a multi-layer substrate 110, a mechanical drill 120 including a drill bit 122, an electrical probe 150, a continuity meter 140, and a controller 130 that controls mechanical drill 120 responsive to continuity meter 140.

As shown in FIG. 1, multi-layer substrate 110 includes a top external surface 101 and a bottom external surface 103 including a plurality of multi-layers (not shown) there between. Main circuit area 111 may include any of various conductive traces such as copper and circuit components such as ball grid arrays (BGAs), quad flatpack no leads (QFNs), resistors, or capacitors (not shown) formed on top external surface 101, bottom external surface 103, and/or within multi-layer substrate 110 on intermediate layers between top external surface 101 and bottom external surface 103. Main circuit area 111 may extend variously or repeatedly over and within multi-layer substrate 110. Test coupon 112 is disposed anywhere outside or separate from main circuit area 111. In representative embodiments, test coupon 112 may be disposed along an edge or periphery of multi-layer substrate 110, or at a central portion of multi-layer substrate 110 separate from main circuit area 111. Test coupon 112 is disposed or formed on an intermediate layer within multi-layer substrate 110 between top external surface 101 and bottom external surface 103. Test coupon 112 may be a conductive trace such a copper trace. Test coupon 112 as shown has a serpentine shape between points 113 and 114. In other representative embodiments, test coupon 112 may have any various shape between points 113 and 114, including a straight line or serpentine lines. Points 113 and 114 of test coupon 112 are respectively connected to probe sites 117 and 118 by conductive traces 115 and 116. In other representative embodiments, points 113 and 114 may be connected to probe sites 117 and 118 without extended conductive traces 115 and 116 there between. Probe sites 117 and 118 may be vias formed entirely through multi-layer substrate 110 and may be disposed along an edge of multi-layer substrate 110. In other representative embodiments, probe sites 117 and 118 may be formed at other areas of multi-layer substrate 110 separate from main circuit area 111 such as a central portion of multi-layer substrate 110. Multi-layer substrate 110 may be a printed circuit board (PCB), a circuit board, a semiconductor material, an insulting material, any combination thereof, or any type of substrate or structure in general. In a representative embodiment, multi-level substrate 110 may be at least one of a semiconductor material and an insulating material.

Mechanical drill 120 as shown in FIG. 1 is configured to be movable laterally in any direction over multi-layer substrate 110 and up/down responsive to controller 130, to drill holes within multi-layer substrate 110. Mechanical drill 120 may be movable to drill holes through multi-layer substrate 110, or partly through multi-layer substrate 110 to any desired depth. Mechanical drill may drill holes through test coupon 112, and/or partly through or entirely through main circuit area 111. In a representative embodiment, mechanical drill 120 may include a plunging head with a plunge depth gauge, and may provide plunge depth location data to controller 130 and may receive plunge stop depth data from controller 130. Drill bit 122 may have a flat tip or a conical tapered tip, and may be any type of drill bit suitable for drilling through the various layers, traces and circuit components of multi-layer substrate 110.

As further shown in FIG. 1, continuity meter 140 is connectable to test and determine electrical continuity of test coupon 112 of multi-layer substrate 110 during drilling by way of electrical probe 150, and is configured to provide a signal to controller 130 at the point in time that continuity of test coupon 112 is broken or lost. That is, continuity meter 140 is configured to provide a signal to controller 130 at a point in time that the trace of test coupon 112 is broken by drilling. Electrical probe 150, which may hereinafter be referred to as electrical probe 150, includes test probes 152 and 154 respectively insertable into or onto probe sites 117 and 118 of multi-layer substrate 110 during drilling. Test probes 152 and 154 of electrical probe 150 are connected to continuity meter 140 by respective wires or cables 142 and 144. In the event that a hole is drilled through any portion of test coupon 112 by drill bit 122 of mechanical drill 120, or through traces 115 and 116, electrical continuity between probe sites 117 and 118 as connected to points 113 and 114 of test coupon 112 will be broken or lost. Accordingly, in a representative embodiment monitoring of electrical continuity of test coupon 112 consists of testing electrical continuity between probe sites 117 and 118 using continuity meter 140. As should be understood and as will be subsequently described, the diameter of drill bit 122 used to drill a hole through test coupon 112 must be sized to ensure that at least one portion of the test coupon 112 is completely disconnected from another portion of the test coupon 112 by drill bit 122.

Controller 130 as shown in FIG. 1 may be a microprocessor, an application specific integrated circuit (ASIC) or any type of computer processing device or circuitry capable of being programmed to provide control data (or signals) such as plunge stop depth data to mechanical drill 120, responsive to indication of continuity/discontinuity provided from continuity meter 140 and plunge depth location data provided from mechanical drill 120. Controller 130 may provide control data to a mechanical translation apparatus (not shown) to move mechanical drill 120 laterally in any direction over multi-layer substrate 110 and up/down to drill holes at various locations and of various depth. In a representative embodiment, controller 130 may provide control data to mechanical drill 120 to start/stop rotation of drill bit 122 and to control forward and reverse drill bit rotation. Responsive to the plunge depth location data, controller 130 may record the actual depth of a hole drilled by drill bit 122 of mechanical drill 120 at a point in time when monitoring by continuity meter 140 indicates that electrical continuity of test coupon 112 is broken or lost, or in other words when monitoring indicates electrical discontinuity of test coupon 112. Controller 130 may be connected to a host device to receive operating instructions and/or settings.

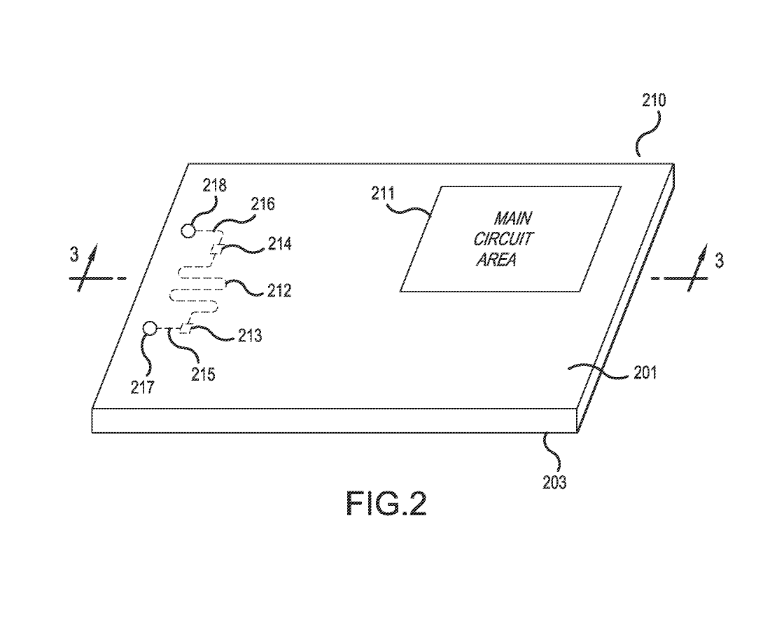

FIG. 2 is a plan view illustrating a multi-layer substrate 210 including a test coupon 212 and a main circuit area 211, according to a representative embodiment. Multi-layer substrate 210 in FIG. 2 includes similar features with somewhat similar reference numerals as multi-layer substrate 110 shown in FIG. 1, and detailed description of such similar features may be omitted from the following.

Referring to FIG. 2, multi-layer substrate 210 includes a top external surface 201 and a bottom external surface 203 including a plurality of multi-layers (not shown) there between. Main circuit area 211 may include any of various conductive traces and circuit components formed on top external surface 201, bottom external surface 203, and/or within multi-layer substrate 210 on intermediate layers between top external surface 201 and bottom external surface 203. Main circuit area 211 may extend variously over and within multi-layer substrate 210. Test coupon 212 is disposed along an edge or periphery of multi-layer substrate 210, separate from main circuit area 211. Test coupon 212 is formed on or disposed over an intermediate layer within multi-layer substrate 210 between top external surface 201 and bottom external surface 203. Test coupon 212 is a conductive trace and has a serpentine shape between points 213 and 214. In other embodiments, test coupon 212 may have a straight shape or other shapes. Points 213 and 214 of test coupon 212 are respectively connected to probe sites 217 and 218 by conductive traces 215 and 216. In other representative embodiments, points 213 and 214 may be connected to probe sites 217 and 218 without extended conductive traces 215 and 216 there between. Probe sites 217 and 218 may be vias formed entirely through multi-layer substrate 210 and are disposed along an edge of multi-layer substrate 210.

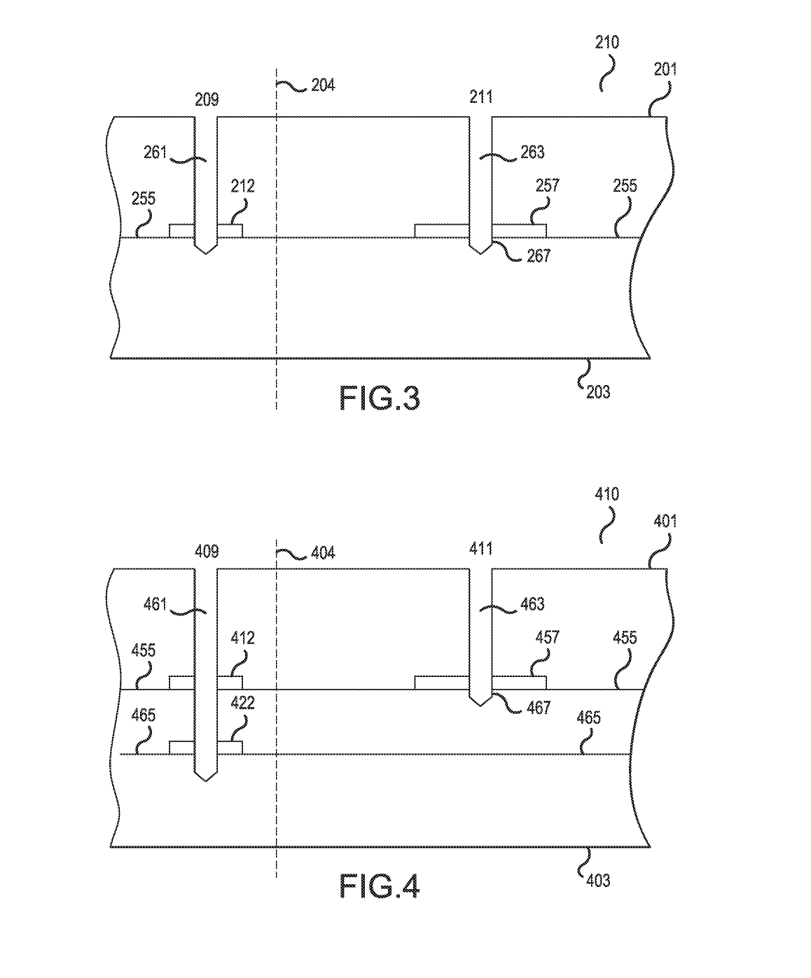

FIG. 3 is a cross-sectional view of multi-layer substrate 210 including a test coupon 212 and a buried target 257, illustrative of a method of forming a blind via according to a representative embodiment. FIG. 3 is a cross-sectional view along line 3-3 shown in FIG. 2.

Referring to FIG. 3, multi-layer substrate 210 includes top external surface 201 (Which may be characterized as a first surface) and bottom external surface 203 (which may be characterized as a second surface), and is separated (by an imaginary line 204) into test area 209 and main circuit area 211. In a representative embodiment, multi-layer substrate 210 may be a single or multiple lamination PCB, and may be manufactured as a plurality of stacked insulator layers with various different conductive traces and circuit components formed on or disposed over the insulator layers. In this representative embodiment, intermediate layer 255 is shown as within multi-layer substrate 210 between top external surface 201 and bottom external surface 203. Buried target 257, which may be a conductive trace or circuit component, is formed on or disposed over intermediate layer 255 within multi-layer substrate 210. Multi-layer substrate 210 may have a thickness within a range of about 0.030 inches to 0.300 inches. In other embodiments, multi-layer substrate 210 may have thickness within different ranges.

To precisely measure and control the depth of a drilled hole to buried target 257 formed on or disposed over intermediate layer 255 within main circuit area 211, to minimize the length of a stub below buried target 257 during formation of the blind via, during manufacture of multi-layer substrate 210 test coupon 212 is formed on or disposed aver intermediate layer 255 within multi-layer substrate 210 in test area 209. In the cross-sectional view of FIG. 3, only a portion of test coupon 212 is shown, while probe sites 217 and 218 and/or traces 215 and 216 are not shown along the corresponding cross-section.

The depth of buried target 257 within multi-layer substrate 210 manufactured to include test coupon 212 as shown in FIG. 3 may be measured indirectly as follows using drilling system 10 shown in FIG. 1.

Controller 130 provides control data to mechanical drill 120 to position mechanical drill 120 over test coupon 212 of test area 209 shown in FIG. 3, and provides control data to continuity meter 140 to begin monitoring electrical continuity of test coupon 212 with test probes 152 and 154 of electrical probe 150 inserted into or onto the corresponding probe sites of test coupon 212.

Controller 130 subsequently provides control data to mechanical drill 120 to begin drilling first hole 261 from top external surface 201 of multi-layer substrate 210 through test coupon 212 and past intermediate layer 255. First hole 261 may have a diameter in a range of about 0.008 inches to 0.018 inches. In other representative embodiments, the diameter of first hole 261 may be within different ranges depending on the corresponding application.

At the point in time that first hole 261 is completely drilled through test coupon 212 so that at least one portion of test coupon 212 is completely disconnected from another portion of test coupon 212, electrical continuity of test coupon 212 is broken or lost, and continuity meter 140 provides a signal to controller 130 indicative of discontinuity of test coupon 212.

Controller 130 then determines the depth of first hole 261 at the point of discontinuity (substantially equivalent to the depth of intermediate layer 255) responsive to the plunge depth location data provided by mechanical drill 120 and the discontinuity signal provided by continuity meter 140.

Since test coupon 212 and buried target 257 are both formed on intermediate layer 255 shown in FIG. 3, the determined, depth of first hole 261 corresponds substantially to the depth of buried target 257. That is, the depth of buried target 257 is determined responsive to monitoring electrical continuity of test coupon 212 during drilling of first hole 261.

A blind via may then be formed connected to buried target 257 formed on or disposed over intermediate layer 255 shown in FIG. 3 responsive to the determined depth of buried target 257, using drilling system 10 shown in FIG. 1.

Controller 130 provides control data to mechanical drill 120 to position mechanical drill 120 over buried target 257 of main circuit area 211 shown in FIG. 3, and to then begin drilling second hole 263 from top external surface 201 of multi-layer substrate 210 to the buried target 257. Controller 130 provides the plunge stop depth data to mechanical drill 120 so that second hole 263 is stopped to have a depth substantially equivalent to the previously determined depth of buried target 257. As shown, second hole 267 has a terminating end within multi-layer substrate 110. Since the plunge stop depth data may be provided responsive to the previously determined depth of buried target 257, drilling of second hole 263 may be more precisely controlled to stop or end in the near vicinity of intermediate layer 255, thereby minimizing drilling overshoot.

Second hole 263 may thereafter be plated with copper or the like using any well known appropriate technique, to form a blind via from the top external surface 201 of multi-layer substrate 210 connected to buried target 257. As a consequence of the minimal drilling overshoot, the length of plated stub 267 is minimized and improved signal quality of an external electrical signal applied to the buried target 257 through the blind via may be maintained. For example, in representative embodiments, plated stub 267 may be minimized to about 0.002 inches, instead of typical stub length which may be 0.020 inches or more.

In a representative embodiment, at least one additional test coupon such as test coupon 212 shown in FIG. 3 may be formed on intermediate layer 255 in another location within multi-layer substrate 210 away from test coupon 212. Respective holes such as first hole 261 shown in FIG. 3 may be drilled through at least one additional test coupon. Continuity meter 140 as shown in FIG. 1 may monitor continuity of the at least one additional test coupon during drilling of the respective holes through the at least one additional test coupon. Controller 130 may determine a depth of the buried target 257 responsive to monitoring of continuity of test coupon 212 and monitoring of continuity of at least one additional test coupon. By the use of additional test coupons located at different locations, the depth of buried target 257 may be more precisely determined.

FIG. 4 is a cross-sectional view of a multi-layer substrate including first and second test coupons 412 and 422 and a buried target 457, illustrative of a method of forming a blind via according to a representative embodiment. Multi-layer substrate 410 in FIG. 4 includes similar features with somewhat similar reference numerals as multi-layer substrate 210 shown in FIG. 3, and detailed description of such similar features may be omitted from the following.

Referring to FIG. 4, multi-layer substrate 410 includes top external surface 401 (which may be characterized as a first surface) and bottom external surface 403 (which may be characterized as a second surface), and is separated (by an imaginary line 404) into test area 409 and main circuit area 411. In a representative embodiment, multi-layer substrate 410 may be a single or multiple lamination PCB, and may be manufactured as a plurality of stacked insulator layers with various different conductive traces and circuit components formed on or disposed over the insulator layers. In this representative embodiment, first intermediate layer 455 is shown as within multi-layer substrate 410 between top external surface 401 and bottom external surface 403. Buried target 457, which may be a conductive trace or circuit component, is formed on or disposed over first intermediate layer 455 within multi-layer substrate 410.

To precisely measure and control the depth of a drilled hole to buried target 457 disposed over first intermediate layer 455 within main circuit area 411, to minimize and precisely control the length of a stub below buried target 457 during formation of the blind via, during manufacture of multi-layer substrate 410 first test coupon 412 is formed on or disposed over first intermediate layer 455 within multi-layer substrate 410 in test area 409. A second test coupon 422 is also formed below first intermediate layer 455 during manufacture of multi-layer substrate 410. Second test coupon 422 may be formed on or disposed over second intermediate layer 465 within multi-layer substrate 410 in test area 409 between first intermediate layer 455 and bottom external surface 403.

The depth of buried target 457 within multi-layer substrate 410 manufactured to include first and second test coupons 412 and 422 as shown in FIG. 4 may be measured indirectly as follows using drilling system 10 shown in FIG. 1.

Controller 130 provides control data to mechanical drill 120 to position mechanical drill 120 over first test coupon 412 and second test coupon 422 of test area 409 shown in FIG. 4, and provides control data to continuity meter 140 to begin monitoring electrical continuity of first test coupon 412 with test probes 152 and 154 of electrical probe 150 inserted into or onto the corresponding probe sites of first test coupon 412.

Controller 130 subsequently provides control data to mechanical drill 120 to begin drilling first hole 461 from top external surface 401 of multi-layer substrate 410 through first test coupon 412 and past first intermediate layer 455.

At the point in time that first hole 461 is completely drilled through first test coupon 412, electrical continuity of first test coupon 412 is broken or lost, and continuity meter 140 provides a signal to controller 130 indicative of discontinuity of first test coupon 412.

Controller 130 determines the depth of first hole 461 at the point of discontinuity of first test coupon 412 (substantially equivalent to the depth of first intermediate layer 455) responsive to the plunge depth location data provided by mechanical drill 120 and the discontinuity signal provided by continuity meter 140 responsive to monitoring of electrical continuity of first test coupon 412.

Controller 130 then provides control data to continuity meter 140 to begin monitoring electrical continuity of second test coupon 422 with test probes 152 and 154 of electrical probe 150 inserted into or onto the corresponding probe sites of second test coupon 422. Controller 130 provides control data to mechanical drill 120 to continue drilling first hole 461.

At the point in time that first hole 461 is completely drilled through second test coupon 422, electrical continuity of second test coupon 422 is broken or lost, and continuity meter 140 provides a signal to controller 130 indicative of discontinuity of second test coupon 422.

Controller 130 determines the depth of first hole 461 at the point of discontinuity of second test coupon 422 (substantially equivalent to a desired lower limit of second hole 463 to be drilled through buried target 457) responsive to the plunge depth location data provided by mechanical drill 120 and the discontinuity signal provided by continuity meter 140 responsive to monitoring of electrical continuity of second test coupon 422.

Since first test coupon 412 and buried target 457 are both formed on first intermediate layer 455 shown in FIG. 4, the determined depth of first hole 461 at the time of discontinuity of first test coupon 412 corresponds substantially to the depth of buried target 457. Moreover, the determined depth of first hole 461 at the time of discontinuity of second test coupon 422 corresponds to the desired lower limit of second hole 463 to be drilled through buried target 457.

Controller 130 then provides control data to mechanical drill 120 to position mechanical drill 120 over buried target 457 of main circuit area 411 shown in FIG. 4, and to then begin drilling second hole 463 from top external surface 401 of multi-layer substrate 410 to the buried target 457. Controller 130 provides the plunge stop depth data to mechanical drill 120 so that second hole 463 is stopped to have a depth substantially equivalent to the previously determined depth of buried target 457, and that is precisely limited between the depth of buried target layer 457 and the desired lower limit of second hole 463 as set by second test coupon 422. Drilling of second hole 463 may be more precisely controlled to stop or end in the near vicinity of first intermediate layer 455, thereby minimizing drilling overshoot.

Second hole 463 may thereafter be plated with copper or the like as previously described with respect to FIG. 3 to form a blind via from the top external surface 401 of multi-layer substrate 410 connected to buried target 457. As a consequence of the minimal drilling overshoot, the length of plated stub 467 is minimized and precisely controlled, and improved signal quality of an external electrical signal applied to the buried target 457 through the blind via may be maintained.

In a representative embodiment, controller 130 as described with respect to FIG. 4 may record a depth of the first hole 461 when continuity meter 140 provides the signal indicative of discontinuity of first test coupon 412, and may record a depth of the first hole 461 when continuity meter 140 provides the signal indicative of discontinuity of second test coupon 422.

In the representative embodiment as described with respect to FIG. 4, first test coupon 412 is shown as having the same size and as aligned directly over second test coupon 422. However, in other representative embodiments first test coupon 412 and second test coupon 422 may have different sizes, and/or may not necessarily be aligned completely over each other. That is, in such other representative embodiments, only the portions of first and second test coupons 412 and 422 through which first hole 461 is drilled may be aligned to overlap.

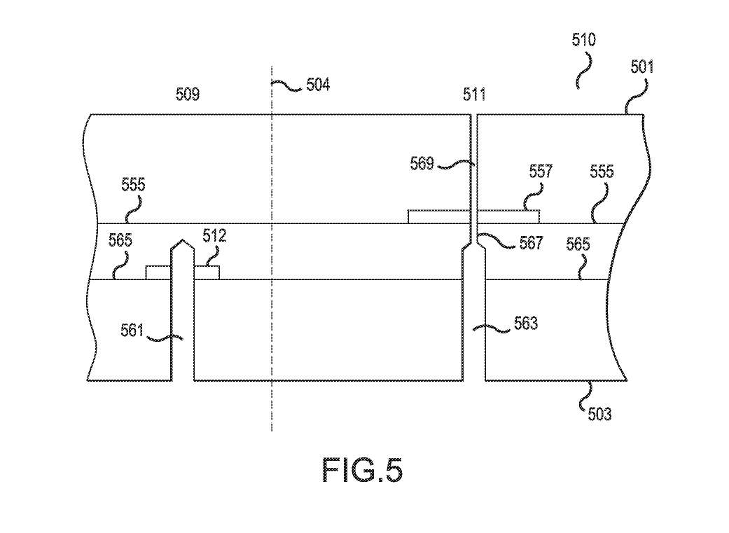

FIG. 5 is a cross-sectional view of a multi-layer substrate including test coupon 512 and a buried target 557, illustrative of a method of forming a through via according to a representative embodiment. In contrast to the blind vias as described with respect to FIGS. 3 and 4, the through via extends entirely through the multi-layer substrate. Multi-layer substrate 510 in FIG. 5 includes similar features with somewhat similar reference numerals as multi-layer substrate 410 shown in FIG. 4, and detailed description of such similar features may be omitted from the following.

Referring to FIG. 5, multi-layer substrate 510 includes top external surface 501 (which may be characterized as a first surface) and bottom external surface 503 (which may be characterized as a second surface), and is separated (by an imaginary line 504) into test area 509 and main circuit area 511. In a representative embodiment, multi-layer substrate 510 may be a single or multiple lamination PCB, and may be manufactured as a plurality of stacked insulator layers with various different conductive traces and circuit components formed on or disposed over the insulator layers. In this representative embodiment, first intermediate layer 555 is within multi-layer substrate 510 between top external surface 501 and bottom external surface 503, and second intermediate layer 565 is within multi-layer substrate 510 between first intermediate layer 555 and bottom external surface 503. Buried target 557, which may be a conductive trace or circuit component, is formed on or disposed over first intermediate layer 555 within multi-layer substrate 510.

To precisely measure and control the depth of a drilled hole from bottom external surface 503 toward buried target 557 disposed over first intermediate layer 555 within main circuit area 511, to minimize the length of a plated stub 567 below buried target 557, during manufacture of multi-layer substrate 510 test coupon 512 is thrilled on or disposed over second intermediate layer 565 within multi-layer substrate 510 in test area 509.

The depth of second intermediate layer 565 within multi-layer substrate 510 manufactured to include test coupon 512 as shown in FIG. 5 may be measured indirectly as follows using drilling system 10 shown in FIG. 1.

Multi-layer substrate 510 is flipped over so that bottom external surface 503 faces upward toward mechanical drill 120 shown in FIG. 1. Controller 130 then provides control data to mechanical drill 120 to position mechanical drill 120 over test coupon 512 of test area 509 shown in FIG. 5, and provides control data to continuity meter 140 to begin monitoring electrical continuity of test coupon 512 with test probes 152 and 154 of electrical probe 150 inserted into or onto the corresponding probe sites of test coupon 512.

Controller 130 subsequently provides control data to mechanical drill 120 to begin drilling first hole 561 from bottom external surface 503 of multi-layer substrate 510 through test coupon 512.

At the point in time that first hole 561 is completely drilled through test coupon 512, electrical continuity of test coupon 512 is broken or lost, and continuity meter 140 provides a signal to controller 130 indicative of discontinuity of test coupon 512.

Controller 130 then determines the depth of first hole 561 at the point of discontinuity (substantially equivalent to the depth of second intermediate layer 565) responsive to the plunge depth location data provided by mechanical drill 120 and the discontinuity signal provided by continuity meter 140.

Since test coupon 512 and second intermediate layer 565 shown in FIG. 5 are at substantially the same level, the determined depth of test coupon 512 corresponds substantially to the depth of second intermediate layer 565 from bottom external surface 503. That is, the depth of second intermediate layer 565 is determined responsive to monitoring electrical continuity of test coupon 512 during drilling of first hole 561.

Controller 130 provides control data to mechanical drill 120 to position mechanical drill 120 over buried target 557 of main circuit area 511 shown in FIG. 5, and to then begin drilling second hole 569 entirely through multi-layer substrate 510 and buried target 557 from bottom external surface 503 to top external surface 501. In other representative embodiments, multi-layer substrate 510 may be flipped over so that top external surface 501 faces upward toward mechanical drill 120 shown in FIG. 1, and so that mechanical drill 120 drills second hole 569 entirely through multi-layer substrate 510 and buried target 557 from top external surface 501 to bottom external surface 503.

Second hole 569 may thereafter be plated with copper or the like as previously described with respect to FIG. 3 to form a through via from the top external surface 501 of multi-layer substrate 510 connected to buried target 557.

Multi-layer substrate 510 is maintained, or in the alternative flipped over, depending on which external surface second hole 569 was drilled from, so that bottom external surface 503 faces upward toward mechanical drill 120 shown in FIG. 1. Controller 130 then provides control data to mechanical drill 120 to position mechanical drill 120 over buried target 557 of main circuit area 511 shown in FIG. 5, and to then begin drilling third hole 563 from bottom external surface 503 of multi-laver substrate 510 toward buried target 557. Mechanical drill 120 is positioned so that a central axial line of third hole 563 is aligned with a central axial line of second hole 569.

Of note, the corresponding drill bit used by mechanical drill 120 to drill third hole 563 has a diameter greater than a diameter of the corresponding drill bit used by mechanical drill 120 to drill second hole 569. That is, the diameter of third hole 563 is greater than the diameter of second hole 569. Accordingly, since the central axial line of third hole 563 is aligned with a central axial line of second hole 569, drilling of third hole 563 effectively removes the plating from second hole 569 from the bottom external surface 503 of multi-layer substrate 510 substantially to the determined depth of second intermediate layer 565. In a representative embodiment, the diameter of second and third holes 569 and 563 may respectively be about 0.012 inches and 0.025 inches. In other representative embodiments, second and third holes 569 and 563 may have different diameters as long as the plating is effectively removed from second hole 569.

Since the plunge stop depth data may be provided to controller 130 responsive to the previously determined depth of second intermediate layer 565, drilling of third hole 563 may be more precisely controlled to stop or end in the near vicinity of first intermediate layer 555 between first and second intermediate layers 555 and 565, thereby minimizing the length that plated stub 567 extends below buried target 557. As a consequence, improved signal quality of an external electrical signal applied to the buried target 557 may be maintained.

In a representative embodiment, first and third holes 561 and 563 as described with respect to FIG. 5 may be drilled after second hole 569.

FIG. 6 is a plan view illustrating a test coupon with a corresponding drill hole at a first location, according to a representative embodiment.

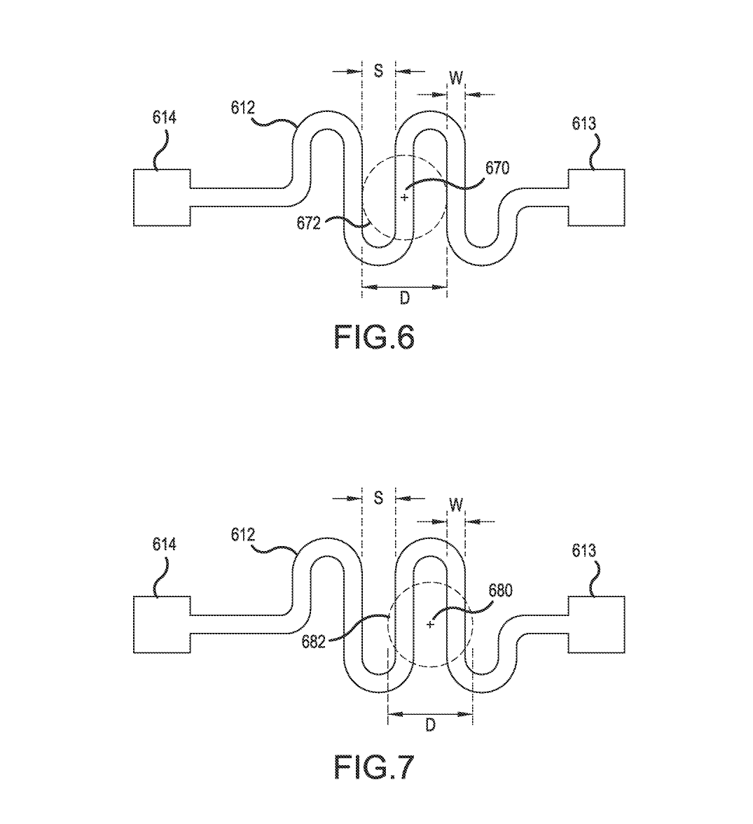

FIG. 7 is a plan view illustrating a test coupon with a corresponding drill hole at a second location, according to a representative embodiment.

Referring to FIG. 6, test coupon 612 between points 613 and 614 is shown as having serpentine shape, with trace width W and trace spacing S, Points 613 and 614 may be considered as corresponding to points 113 and 114 shown in FIG. 1 and points 213 and 214 as shown in FIG. 2. A corresponding hole to be drilled through test coupon 612 is shown as centered at target point 670 and as having diameter D. As long as the diameter D of the drill bit is greater than trace width W, continuity of the test coupon 612 will be broken when the drilled hole 672 is centered on a trace at target point 670 as shown in FIG. 6.

In a representative embodiment, the drill diameter D may be defined as follows:

D>(S+2W) (1)

Referring to FIG. 7, if the diameter D of the drill bit is selected in accordance with equation (1), continuity of test coupon 612 will be broken in the event that the drilled hole 682 is shifted to be centered at target point 680 between adjacent traces of test coupon 612 as shown in FIG. 7. That is, even if the drill bit is misaligned during drilling of a hole through test coupon 612, if the drill diameter D is selected in accordance with equation (1), continuity of at least one trace of test coupon 612 will be broken, thus ensuring that continuity may be broken as intended to enable measuring depth of test coupon 612.

In the representative embodiment as described with respect to FIG. 4, in the case that first and second test coupons 412 and 422 are both serpentine shaped with trace width W and trace spacing S and a drill diameter D is selected in accordance with equation (1), it may be ensured that continuity of first and second test coupons 412 and 422 will be broken in the event that first and second test coupons 412 and 422 are not perfectly aligned with respect to each other.

In the representative embodiments the test coupons such as test coupon 112 shown in FIG. 1 are described as having any various shape between points such as points 113 and 114 shown in FIG. 1. The test coupons of the representative embodiments, such as test coupon 112 shown in FIG. 1 may however be characterized as a trace with probe sites 117 and 118 at opposite ends, whereby the trace of the test coupon includes traces 115 and 116, points 113 and 114 and test coupon 112 shown in FIG. 1 for example. That is, the test coupon may generally be characterized as including traces 115 and 116, points 113 and 114 and test coupon 112. The hole may thus be characterized as drilled through the trace of the test coupon anywhere along traces 115 and 116, points 113 and 114 and test coupon 112 shown in FIG. 1.

The phrase “and/or,” as used herein in the specification and in the claims, should be understood to mean “either or both” of the elements so conjoined. In the claims, as well as in the specification above, all transitional phrases such as “comprising.” “including,” “carrying,” “having,” “containing,” “involving,” “holding,” “composed of,” and the like are to be understood to be open-ended, i.e., to mean including hut not limited to. Only the transitional phrases “consisting of” and “consisting essentially of” shall be closed or semi-closed transitional phrases, respectively.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

Therefore the invention should not be limited to the particular example embodiments described in detail above.

While example embodiments are disclosed herein, one of ordinary skill in the art appreciates that many variations that are in accordance with the present teachings are possible and remain within the scope of the appended claims. The invention therefore is not to be restricted except within the scope of the appended claims.

1. A method of detecting depth of a buried target disposed over an intermediate layer within a multi-layer substrate, comprising:
forming a test coupon over the intermediate layer during manufacture of the multi-layer substrate, the test coupon comprising a trace with probe sites at opposite ends;
drilling a hole through the trace of the test coupon within the multi-layer substrate;
monitoring electrical continuity of the test coupon during said drilling; and
determining a depth of the buried target responsive to said monitoring.

2. The method of claim 1, wherein said monitoring comprises testing electrical continuity between the probe sites using a continuity meter.

3. The method of claim 2, wherein the probe sites comprise vias formed through the multi-layer substrate.

4. The method of claim 1, wherein the trace comprises a serpentine shape.

5. (canceled)

6. The method of claim 1, further comprising:
forming a second test coupon below the intermediate layer during manufacture of the multi-layer substrate, the second test coupon comprising a trace with probe sites at opposite ends;
drilling the hole through the trace of the second test coupon within the multi-layer substrate; and
monitoring electrical continuity of the second test coupon during said drilling through the second test coupon,
wherein said determining is further responsive to said monitoring electrical continuity of the second test coupon.

7. The method of claim 1, wherein the multi-layer substrate comprises a circuit board.

8. The method of claim 1, wherein the multi-layer substrate comprises at least one of semiconductor material and insulating material.

9.-10. (canceled)

11. A method of connecting a via to a buried target disposed over an intermediate layer within a multi-layer substrate, comprising:
forming a test coupon over the intermediate layer during manufacture of the multi-layer substrate, the test coupon comprising a trace having probe sites at opposite ends;
drilling a first hole through the trace of the test coupon within the multi-layer substrate;
monitoring electrical continuity of the test coupon during said drilling of the first hole;
determining a depth of the buried target responsive to said monitoring;
drilling a second hole to the buried target within the multi-layer substrate, the second hole having a depth selected responsive to the determined depth; and
plating the second hole to form a via connected to the buried target.

12. The method of claim 11, wherein the first hole is drilled from a first surface of the multi-layer substrate and the second hole is drilled from the first surface of the multi-layer substrate, the second hole having a terminating end within the multi-layer substrate.

13.-15. (canceled)

16. The method of claim 11, further comprising:
forming a second test coupon below the intermediate layer during manufacture of the multi-layer substrate, the second test coupon comprising a trace with probe sites at opposite ends;
drilling the first hole through the trace of the second test coupon within the multi-layer substrate; and
monitoring electrical continuity of the second test coupon during said drilling through the second test coupon,
wherein said determining is further responsive to said monitoring electrical continuity of the second test coupon.

17-20. (canceled)

21. A drilling system configured to detect a depth of a buried target in an intermediate layer of a multi-layer substrate having, a test coupon disposed therein, the test coupon comprising a trace with probe sites at opposite ends, the system comprising:
a drill configured to drill a hole through the trace of the test coupon within the multi-layer substrate;
a continuity meter configured to monitor the test coupon during drilling by the drill; and
a controller configured to determine a depth of the buried target responsive to the continuity meter.

22. The drilling system of claim 1, wherein the continuity meter tests electrical continuity between the probe sites.

23. The drilling system of claim 2, wherein the probe sites comprise vias formed through the multi-layer substrate.

24. The drilling system of claim 1, wherein the trace comprises a serpentine shape.

25. The drilling system of claim 1, wherein a second test coupon is disposed below the intermediate layer during manufacture of the multi-layer substrate, the second test coupon comprising a second trace with second probe sites at the opposite ends, wherein the drilling system is further configured to:
drill respective holes through the second trace of the second test coupon within the multi-layer substrate; and
monitor electrical continuity of the second test coupon during the drilling; and the controller is further configured to determine a depth of the buried target is responsive to the continuity meter.

27. The drilling system of claim 1, wherein the multi-layer substrate comprises a circuit board.

28. The drilling system of claim 1, wherein the multi-layer substrate comprises at least one of semiconductor material and insulating material.

30. The drilling system of claim 1, wherein the controller is configured to record a depth of the hole when said monitoring indicates electrical discontinuity of the test coupon.
